(19) United States
(12) Patent Application Publication
(10) Pub. No.: US 2006/0159111 A1
(43) Pub. Date: Jul. 20, 2006

(54) Scaleable controlled interconnect with optical and wireless applications

(75) Inventors: Coke S. Reed, Cranbury, NJ (US); David Murphy, Austin, TX (US)

Correspondence Address: KOESTNER BERTANI LLP, 18662 MACARTHUR BLVD, SUITE 400, IRVINE, CA, 92612, US

(73) Assignee: Interactic Holdings, LLC

(21) Appl. No.: 11/314,175

(22) Filed: Dec. 20, 2005

Related U.S. Application Data
(60) Provisional application No. 60/638,068, filed on Dec. 20, 2004.

(51) Int. Cl. G01R 31/08; H04L 12/26; H04L 1/00; H04L 12/56; H04L 12/28

(52) U.S. Cl. 370/401; 370/229

(57) ABSTRACT

An interconnect structure comprises a plurality of network-connected devices and a logic adapted to control a first subset of the network-connected devices to transmit data and simultaneously control a second subset of the network-connected devices to prepare for data transmission at a future time. The logic can execute an operation that activates a data transmission action upon realization of at least one predetermined criterion.

### RELATED PATENT AND PATENT APPLICATIONS

The disclosed system and operating method are related to subject matter disclosed in the following patents and patent applications that are incorporated by reference herein in their entirety:

1. U.S. Pat. No. 5,996,020 entitled, “A Multiple Level Minimum Logic Network”, naming Coke S. Reed as inventor;

2. U.S. Pat. No. 6,289,021 entitled, “A Scaleable Low Latency Switch for Usage in an Interconnect Structure”, naming John Hesse as inventor;

3. U.S. Pat. No. 6,754,207 entitled, “Multiple Path Wormhole Interconnect”, naming John Hesse as inventor;

4. U.S. Pat. No. 6,687,253 entitled, “Scalable Wormhole-Routing Concentrator”, naming John Hesse and Coke Reed as inventors;

5. U.S. patent application Ser. No. 09/693,603 entitled, “Scaleable Interconnect Structure for Parallel Computing and Parallel Memory Access”, naming John Hesse and Coke Reed as inventors;

6. U.S. patent application Ser. No. 09/693,358 entitled, “Scalable Interconnect Structure Utilizing Quality-Of-Service Handling”, naming Coke Reed and John Hesse as inventors;

7. U.S. patent application Ser. No. 09/692,073 entitled, “Scalable Method and Apparatus for Increasing Throughput in Multiple Level Minimum Logic Networks Using a Plurality of Control Lines”, naming Coke Reed and John Hesse as inventors;

8. U.S. patent application Ser. No. 09/919,462 entitled, “Means and Apparatus for a Scaleable Congestion Free Switching System with Intelligent Control”, naming John Hesse and Coke Reed as inventors;

9. U.S. patent application Ser. No. 10/123,382 entitled, “A Controlled Shared Memory Smart Switch System”, naming Coke S. Reed and David Murphy as inventors;

10. U.S. patent application Ser. No. 10/289,902 entitled, “Means and Apparatus for a Scaleable Congestion Free Switching System with Intelligent Control II”, naming Coke Reed and David Murphy as inventors;

11. U.S. patent application Ser. No. 10/798,526 entitled, “Means and Apparatus for a Scalable Network for Use in Computing and Data Storage Management”, naming Coke Reed and David Murphy as inventors;

12. U.S. patent application Ser. No. 10/866,461 entitled, “Means and Apparatus for Scalable Distributed Parallel Access Memory Systems with Internet Routing Applications”, naming Coke Reed and David Murphy as inventors;

13. U.S. patent application Ser. No. 10/887,762 entitled, “Means and Apparatus for a Self-Regulating Interconnect Structure”, naming Coke Reed as inventor

14. U.S. patent application Ser. No. ______ entitled, “Means and Apparatus for a Scaleable Congestion Free Switching System with Intelligent Control III”, naming John Hesse, Coke Reed and David Murphy as inventors;

15. U.S. patent application Ser. No. ______ entitled, “Highly Parallel Switching Systems Utilizing Error Correction”, naming Coke Reed and David Murphy as inventors;

16. U.S. patent application Ser. No. ______ entitled, “Highly Parallel Switching Systems Utilizing Error Correction II”, naming Coke Reed and David Murphy as inventors; and

17. U.S. patent application Ser. No. ______ entitled, “Apparatus for Interconnecting Multiple Devices to a Synchronous Device”, naming Coke Reed as inventor.

### BACKGROUND

Interconnect network technology is a fundamental component of computational and communications products ranging from supercomputers to grid computing switches to a growing number of routers. However, characteristics of existing interconnect technology result in significant limits in scalability of systems that rely on the technology.

### SUMMARY

An interconnect structure comprises a plurality of network-connected devices and a logic adapted to control a first subset of the network-connected devices to transmit data and simultaneously control a second subset of the network-connected devices to prepare for data transmission at a future time. The logic can execute an operation that activates a data transmission action upon realization of at least one predetermined criterion.

### BRIEF DESCRIPTION OF THE DRAWINGS

Embodiments of the illustrative systems and associated technique relating to both structure and method of operation, may best be understood by referring to the following description and accompanying drawings.

FIG. 1 is a schematic block diagram that illustrates a collection of computing or data storage devices interconnected by an uncontrolled network and a controlled network.

FIG. 2A is a schematic block diagram showing a controlled portion of a network comprising K switches connecting N devices.

FIG. 2B is a schematic block diagram depicting input and output ports of one of the N devices illustrated in FIG. 2A.

FIG. 2C is a schematic block diagram that illustrates a multicasting circuit contained in one of the K switches illustrated in FIG. 2A.

FIG. 3A is a block diagram illustrating a data-passing portion of an optical network which is based on multiple wavelengths.

FIG. 3B is a block diagram illustrating input and output ports of a computing device illustrated in FIG. 3A.

FIG. 4A is a block diagram illustrating N devices which employ a wireless network for data transmission and the wireless network being used is controlled by a Data Vortex™ network switch.

FIG. 4B is a block diagram illustrating input and output ports of a computing device illustrated in FIG. 4A

FIG. 5A is a schematic pictorial diagram illustrating a four-cylinder, eight-row network that exemplifies multiple-level, minimum-logic (MLML) networks.

FIG. 5B is a schematic diagram that shows a stair-step interconnect structure.

FIGS. 6A through 6F are schematic block diagrams showing various embodiments and aspects of a congestion-free switching system with intelligent control.

FIG. 7A is a schematic block diagram that illustrates multiple computing and data storage devices connected to both a scheduled network and an unscheduled network.

FIG. 7B is a schematic block diagram showing the system depicted in FIG. 7A with the addition of control lines associated with the unscheduled switch.

### DETAILED DESCRIPTION

The disclosed structures and methods may be used to couple multiple devices using a plurality of interconnects and may be used for the controlled interconnection of devices over an optical or wireless medium. An aspect of the illustrative structures and methods involves control of a set of interconnection mediums wherein, at a given time, a subset of the interconnection mediums transmit data while another subset of the interconnection mediums are set for transmission of data at a future time.

A wide variety of next generation parallel computing and data storage systems may be implemented on a high-bandwidth, low-latency interconnect network capable of connecting an extremely large number of devices. Optical and wireless network fabrics enable a very high-bandwidth, large-port-count switch. However, these systems have not been widely employed in packet based systems because of the lack of an efficient management scheme in conventional usage. The present disclosure describes an efficient solution to the problem that is based on the Data Vortex™ switch described in related patents and applications 1, 2, 3, 6, 7, 13, 15, and 17.

References 8 and 10 show how the flow of telecommunication data through a switch fabric, including a stack of Data Vortex™ stair-step switch chips, can be managed by a system incorporating Data Vortex™ switches. References 11, 15, and 16 show how, in computing and storage area network systems, the flow of data through a collection of data carrying stair-step Data Vortex™ switch chips can be managed by another Data Vortex™ chip that carries control information. Reference 14 shows how the flow of data through a collection of optical telecommunication switches can be controlled by a system employing an electronic Data Vortex™ switch. The structures and methods disclosed herein depict how the flow of data through a collection of optical or wireless switches for computing and data management purposes can be managed by a system employing an electronic Data Vortex™ switch.

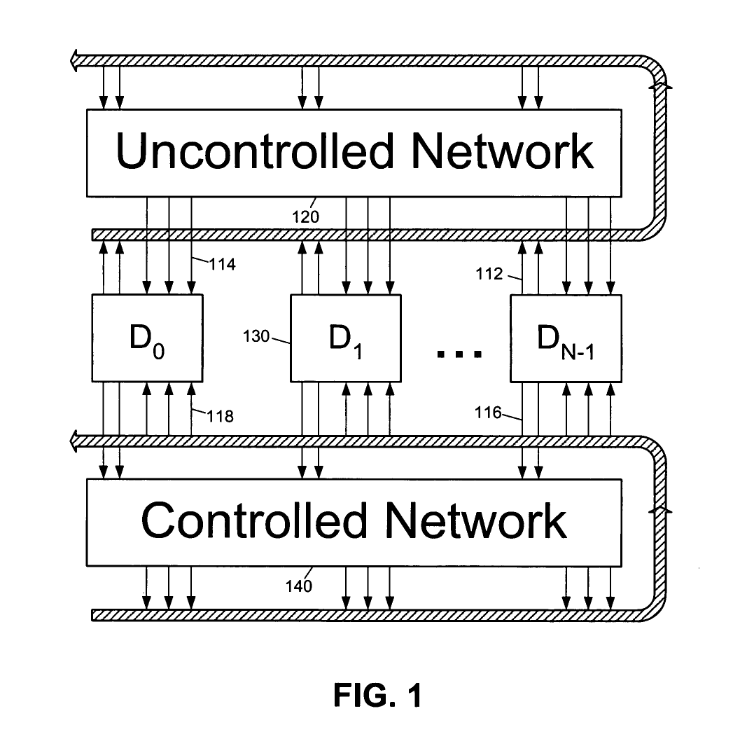

Referring to FIG. 1A, a collection of N devices D₀, D_{1,} . . . , D_{N-1} 130 are illustrated connected by an uncontrolled network 120 and a controlled network 140. The devices may comprise computational elements, random access memory, or mass storage devices. The uncontrolled network carries short packets. The packets may comprise short data packets or may be packets used for control. In many embodiments, the uncontrolled network is a Data Vortex™ network. In a number of the references incorporated herein, the controlled network comprises one or more stacks of stair-step Data Vortex™ chips. The present disclosure describes systems in which the controlled network may be optical or wireless. In one embodiment, the uncontrolled network is an electronic Data Vortex™. The N devices are able to transmit packets to the uncontrolled network over a plurality of data paths. In many embodiments, the number of data paths from the uncontrolled network to the devices exceeds the number of data paths from the devices to the uncontrolled network. The design enables multiple devices to send data simultaneously to a designated receiving device, a feature that enables smooth network operation even in the presence of heavy bursts of traffic. The devices have a plurality of input lines from the uncontrolled network. In some embodiments, one or more of the input lines is reserved for multicast messages.

One type of packet may be used in operation of the system is a “request-to-send data packet” (RTS). The packet has multiple fields. In one illustrative embodiment, the “request-to-send packet” includes a field F₁ that describes the data to be sent. The field F₁ may point to the physical location of the data. Field F₁ may indicate the amount of data to be sent. Field F₁ may give some other information that identifies the data to be sent. A field F₂ can designate the target device for the data. In embodiments in which the devices have multiple input ports, the field F₃ can indicate the target input port of the target device. The field F₄ can be used to assign priority to the request. A field F₅ designates one or more criteria that are to be realized to enable sending of the data. The criteria may include the time for the data to be transmitted by the sending device or the time that the data is to be received by the receiving device. In another mode of operation, the field F₅ can indicate the earliest time that the receiving device will be prepared to receive the data.

The fields may be exploited in multiple ways. In a system wherein a device is scheduled to receive data at a designated time at a designated device input port and the receiving device has access to the designated time and the port information, the operation code prescribed for the incoming data may be embedded in the time and location fields. The RTS packet can be sent to a device through an unscheduled network or can be embedded in a long packet being sent to the device. In the latter case, the RTS may inform the receiving device what action to take after the long packet is received.

In a first example, the system can be used in a message passing computing environment wherein the computational devices perform the same function on different data sets. In a general case, the processing times for the various data sets are not equal. When all of the processors have completed their tasks and reported to a master processor, the master processor sends RTS packets to all processors that are to send or receive data. The master processor has information relating to the status of all input ports and output ports of the computational device. Therefore, for each packet to be sent the associated RTS packet can designate the target input port of a target processor. In case a message longer than a single packet is to be sent, the entire stream of packets containing the message can be scheduled for sending in consecutive time intervals. The sending processor has the instruction from the RTS to send when a certain condition is satisfied, and the receiving processor has the instruction to be prepared to receive during the receiving time interval specified in the RTS packet.

In a second shared-memory example, a receiving processor sends an RTS packet to a sending processor requesting certain data to be sent as soon as possible. In case the receiving processor requests the data be sent through the controlled network, the receiving processor designates a target input port and holds that port open until the data has arrived. In case the receiving processor requests data through the uncontrolled network, the receiving processor does not indicate a receiving processor target input port. The data is sent by the sending processor as soon as all of the criteria in the RTS packet are realized. The criteria include the following: 1) the data is available at the sending processor and 2) the sending processor has a free output port into the scheduled network. In case the data is transmitted over the controlled network, the receiving processor does not request another message be sent to the input port designated for the incoming data packet until that packet has begun to arrive. Once the data begins to arrive at the receiving processor, the receiving processor has information relating to when the transmission of the message is to end, and thus can make a request that data from another sending processor be sent to the same receiving port. In this case, one of the fields in the RTS packet designates the earliest time that the data can be accepted at this input port by the receiving processor. The model of computation in the second mode of operation may be possible using a parallel program language such as UPC.

In a third mode of operation, the flow of data among all or a subset of all devices is handled by a master processor that controls the time and location for sending and receiving of each packet. The model of computation enables streams of data to arrive at processors at the exact time that the data is used to perform the computations. The mode is enabled because the time of flight of messages is known in advance. The following small example illustrates the operation mode. A designated device D_{C} is scheduled to receive data stream A from device D_{A} through device D_{C} data input port IP_{A}, commencing at time t₀ and ending at time t_{E}. Device D_{C} is also scheduled to receive data stream B from device D_{B} through device D_{C} data input port IP_{B}, also commencing at time t₀ and ending at time t_{F}. Device D_{C} is scheduled to perform a function on the streams A and B to produce a stream X that is scheduled to be transmitted to a given input port of another device D_{D}, commencing at time t_{U} and ending at time t_{V}, where t_{U}>t₀. The device D_{D} may also be scheduled to receive a plurality of data streams concurrently with the stream X. The method of systolic processing is enabled by the ability of the system to transmit multiple messages to a designated device with the arrival time of the various messages known because of the deterministic latency through the controlled network. The model of computation described in the third illustrative example can be enabled by extending a parallel language such as UPC to handle the scheduling of times.

The illustrative structures and methods enable a wide range of computation models.

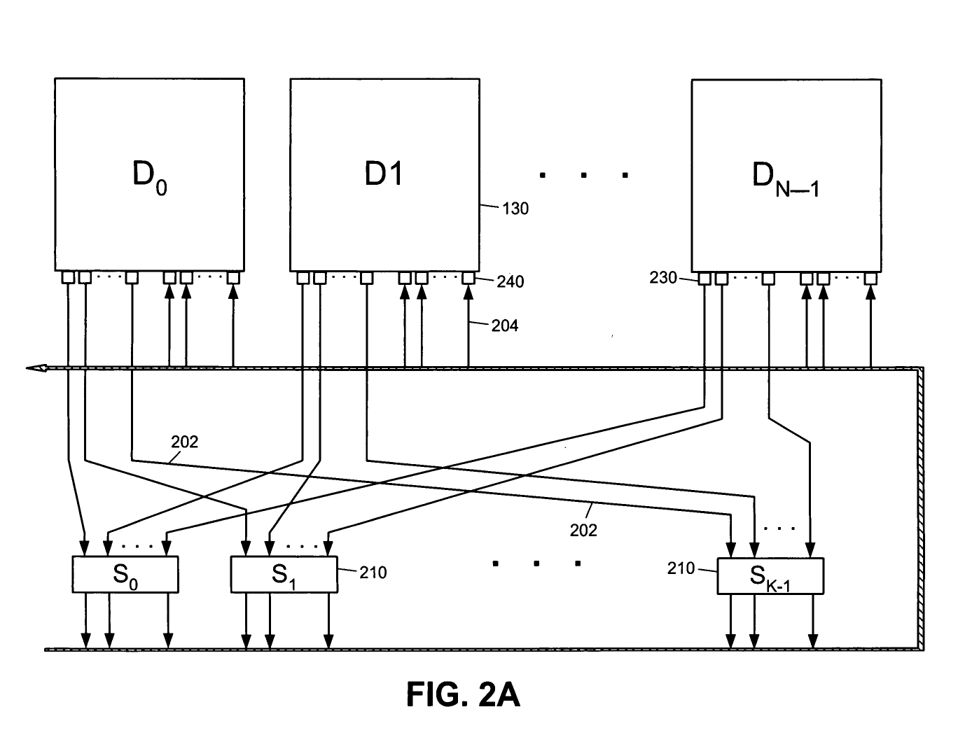

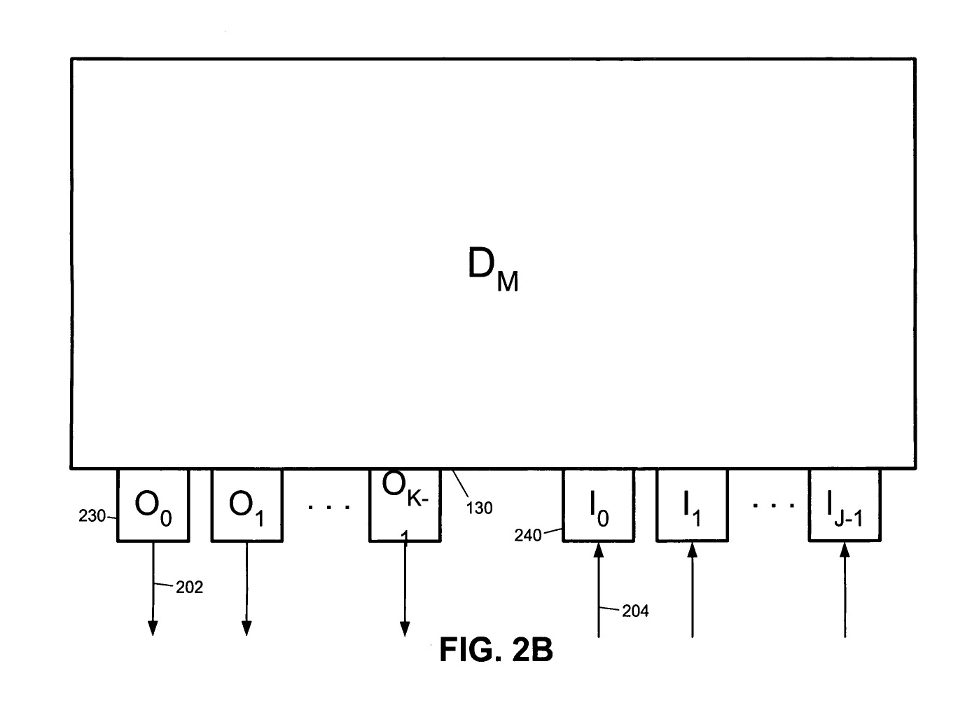

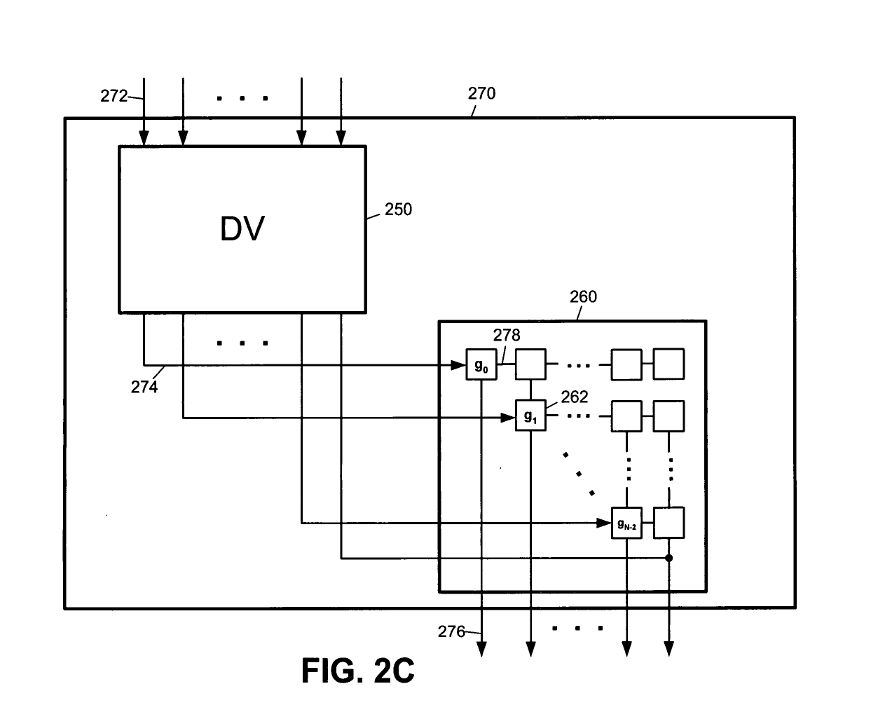

FIG. 2A illustrates a controlled network connecting the N devices D₀, D₁, . . . , D_{N-1} 130. Switches S₀, S₁, . . . , S_{K-1} may be of a type that switch slowly, for example some optical switches, so that if only one of the switches is used then either the packets have a very long length or the lines 202 are usually idle. To illustrate this point, suppose that each packet in the system contains NB bytes and also between adjacent packets is a time of length Δ (“dead time”) when no data is transmitted. Suppose moreover that the data rate through lines 202 is such that NB bytes of data take T_{P} units of time to pass. If K is an integer such that a switch can be set in (K−1)·(T_{P}+Δ) units of time or less, then data flow through the system uses the switches S_{X} in a round robin scheme defined as follows: A packet flows through switch S₀ during the time interval TI₀=[t₀, t₀+T_{P}] and through switch S₁ during the time interval TI₁=[t₀+T_{P}+Δ, t₀+2T_{P}+Δ], and through the switch S₂ during the time interval TI₂=[t₀+2T_{P}+2Δ, t₀+3T_{P}+2Δ], and so forth, so that another packet passes through switch S₀ during the time interval TI_{K}=[t₀+KT_{P}+KΔ, t₀+(K+1)T_{P}+KΔ]. During a time interval expressed as TI_{W}, where W is the modulo K value of the actual time interval, the processors send data through switch S_{W}. During time interval TI_{W+1} through time interval TI_{W-1}, no data is sent through switch S_{W}. Since the time interval has length (K−1)·(T_{P}+Δ), the maximum time for the processors to reset a switch, the processors use the interval to send new switch setting information to switch S_{W}. Thus, prior to the time interval TI_{W}, the switch S_{W} is properly set to carry data during the time interval TI_{W}. All switches in FIG. 2A are set in this manner. Setting information can be sent over the same lines as the data or may be sent over separate electronic lines. In case the setting information is carried over separate electronic lines, setting information for the next data transmission can be transmitted to S_{W} at the same time that S_{W} is carrying data.

Permission to send a packet from a device D_{A} to a device D_{B} through the controlled network is obtained by a request-to-send data packet RTS through the uncontrolled network to D_{B}. In response to the request-to-send packet, device D_{B} reserves an input line for the incoming data during the proper data receiving interval or intervals in case a message comprising multiple packets is sent.

The uncontrolled network manages traffic through the controlled network. The entire system works effectively because, in some embodiments, the Data Vortex™ is a building block of the uncontrolled network. In response to an RTS packet traveling through the uncontrolled network to a sending device D_{S}, the sending device sends information that is used, along with information from other sending devices, to set the proper switches in the set of switches S₀, S₁, . . . , S_{K-1}. As soon as the data passes through one of the switches S_{A}, all devices may send switch setting information to switch S_{A}. Packets of an entire message comprise PN packets that can be sent in contiguous order through the switches with the first packet sent through S_{A}, the second packet sent through S_{A+1}, and so forth, until the last packet is sent through S_{A+PN-1}. The illustrative subscripts are expressed modulo K.

In one optical embodiment, switch S_{A} has the topology of a stair-step Data Vortex™ switch. ES_{A}, an electronic, stair-step Data Vortex™ copy of S_{A}, uses copies of the headers of messages that are sent through the switch S_{A} to determine how to set the nodes in S_{A}. Nodes in the optical switch S_{A} are then set to the same setting as the nodes in ES_{A}. Nodes in the optical Data Vortex™ switch can be of a type that switch slowly, and are therefore relatively inexpensive and have low power requirements. In other embodiments, the switch S_{A} is some other type of optical switch. While the switch S_{A} is being set, data travels through the switches S_{A+1}, S_{A+2}, . . . , S_{K-1}, S₀, . . . , S_{A-1}, with the subscripts expressed modulo K.

FIG. 2B illustrates input and output ports of the device D_{M}. Some output ports may be positioned to send packets to the uncontrolled switch 120, shown in FIG. 1, but not in FIGS. 2A or 2B. In one embodiment, the device D_{M} 130 has K output ports 230 to the controlled switch with the output port O_{A} connected to send data to switch S_{A}. In other embodiments, the device has more than K outputs to the controlled switch so a device can send multiple messages in the same time period. In some applications, each of the output ports comprises one or more modulated lasers. In a case using multiple lasers, packets can be sent in wave division multiplex WDM form. Packets do not need to have a header carrying target address information because the switches S₀, S₁, . . . , S_{N-1} are preset.

Devices 130 each have a plurality of input ports. Some of the input ports may be positioned to receive packets that pass through the uncontrolled switch 120, shown in FIG. 1, but not in FIGS. 2A 2B. Other input ports 240 may be positioned to receive packets that pass through the controlled data switches 210. Still other input ports may be positioned to receive multicast packets from the controlled data switches, while other input ports are positioned to receive multicast packets from the uncontrolled data switch.

FIG. 2C illustrates an electronic version of an uncontrolled switch 290 that is suitable for multicasting data among a set of N devices D₀, D₁, . . . , D_{N-1}. The set of devices is divided into a collection of subsets with the property that no device is in more than one subset and each subset contains at least two devices. The subsets of the set of devices may be called multicast groups. Since the multicast groups are mutually exclusive, the maximum number of groups is limited to N/2 since each group has at least two members. Each group may have a unique member that may be designated the multicast representative for the group. In the presented illustrative embodiment, the multicast representative for a group is designated to be the device in the group with the smallest assigned subscript. The multicast group with multicast representative D_{K} is denoted by G_{K}. No group G_{N-1} exists since, as defined above, such a group would contain only one member. Other schemes for defining multicast groups are apparent. One-bit field in a packet header is reserved multicasting. In one embodiment, the one-bit field is set to zero to indicate that the message is not to be multicast and is set to one to indicate that the message is to be multicast. A packet that is to be multicast to the multicast group G_{K} has a header that contains a one in the multicast field and also contains the target output port address of D_{K}. A logic element in the system may manage the multicast groups and send multicast update parameters to other units in the system whenever the structure of the groups changes. The logic element may, for example, be located in one of the N devices 130.

The switch 290 has two components. The first component is a Data Vortex™ switch DV 250 that receives data packets from the devices D₀, D₁, . . . , D_{N-1} on lines 272 and sends the data packets to the appropriate output line 274 as specified in the header of the packet. In the example illustrated, the leftmost input line 272 receives packets from device D₀, the second from left input line receives packets from device D₁, and so forth, so that the rightmost line receives packets from D_{N-1}. Likewise, the output lines 274 from DV are ordered from left to right and send packets to the devices D₀, D₁, . . . , D_{N-1} respectively.

The second component of the system is a unit 260 which contains N-1 rows of switches 262, one row for each possible group G₀, G₁, . . . , G_{N-2}, with the row associated with G₀ at the top and the row associated with G_{N-2} at the bottom. Each row K for rows 0≦K≦N-2 contains N-K switches, one switch for each possible member of group G_{K}. Switches in each row are arranged in ascending order from left to right in device order. Lines 276 exiting the system from the component are also ordered from left to right and send packets to the devices D₀, D₁, . . . , D_{N-1} respectively. The rightmost line 274 passes through unit 260, sending packets directly to device D_{N-1} on the rightmost line 276. The first switch 262 on each row K is labeled g_{K} and performs two simple functions: 1) g_{K} sends each packet received down line 276 to device D_{K}, and 2) g_{K} examines the multicast bit in the header of the packet and sends the packet on line 278 to the next switch in the row associated with device D_{K+1} only if the bit is turned on, for example equal to one. Other switches in row K also perform two simple functions, first for a switch that is not the last switch in the row the packet or a copy of the packet is sent to the switch to the right, and second if the group bit for the switch is set on, equal to one, the packet is sent on line 276 to the device associated with the switch. Group bits for the switches 262 are set by the multicast logic element previously discussed.

In one embodiment, a separate switch chip is used to carry multicast messages through the uncontrolled switch. The electronic uncontrolled switch is therefore able to handle short multicast messages efficiently.

One method of multicasting longer messages in the controlled network includes building an optical version of the electronic switch illustrated in FIG. 2C. Another method is as follows. A sending device D_{S} that initiates multicast to a multicast group of devices G, sends a special time and place (TAP) multicast message through the uncontrolled electronic switch 210 to the members of device group G indicating to the devices in group G that the devices are to receive a message through a designated multicast port at a specific time. In response to the to the TAP message, the multicast group members open the designated multicast port at the specified time. In the absence of such a message, the devices leave the multicast port closed. At the specified time, the message is sent to all of the devices, but is only received by the devices in G. In other embodiments, the devices have multiple ports for receiving long multicast messages so that devices from different groups can receive multicast messages simultaneously. The method of multicasting does not utilize the switches S₀, S₁, . . . , S_{N-1}, and therefore, the method of multicasting can be used in conjunction with systems that do not contain the switches.

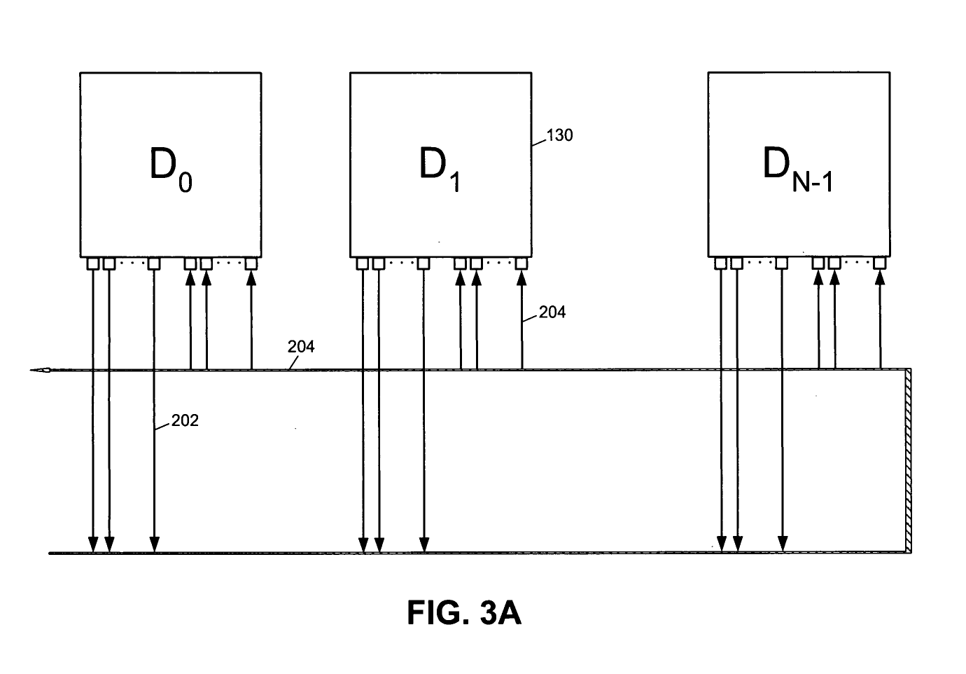

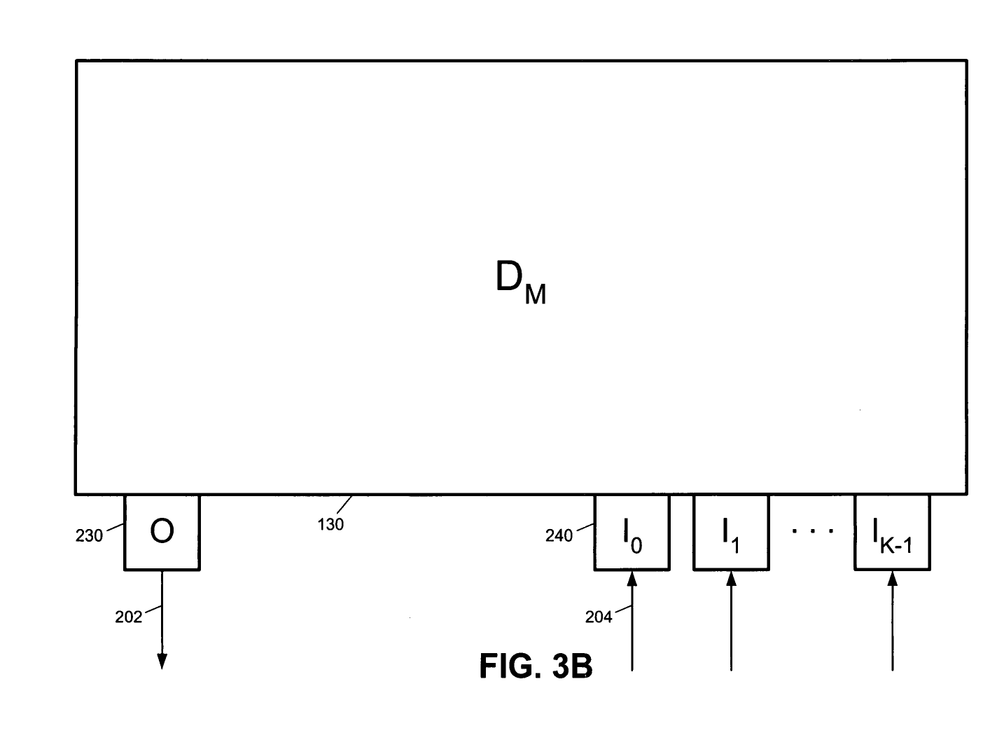

FIG. 3A illustrates the controlled network portion of an optical system that also uses an uncontrolled network. In one embodiment corresponding to FIG. 3A, the uncontrolled network is an electronic Data Vortex™. In a first embodiment illustrated in FIG. 2B, each of the output ports 230 O₀, O₁, . . . , O_{K-1} is a tunable laser. Each of the inputs ports 240 I₀, I₁, . . . , I_{J-1} is an optical input port that has a filter and thus receives only one of the wavelengths that the devices 130 are capable of transmitting from an output port 230. Data is passed from a sending device D_{S} to a specified input port I_{P} of a receiving device D_{R} as follows. Processor D_{S} sends a packet PKT_{SR} optically down fiber 202 on a carrier wavelength λ_{SR}. Signals from a plurality of packets are multiplexed and all of the signals arrive at the input port I_{P} of processor D_{R}. The input port I_{P} filter is used to select the wavelength λ_{SR} and, in embodiments with an electronic device D_{R}, the optical signal is converted to an electronic signal. In some embodiments, packet PKT is sent in multiple wavelengths and is received by a plurality of input ports of the device D_{R}, with each of the input ports I_{Q} having the ability to read an associated unique wavelength λ_{Q}.

Management of the system illustrated in FIG. 3A may be the same as the management of the system illustrated in FIG. 2A. The uncontrolled network is used to control the flow of data though the controlled network. While data is passing through the set of output ports O_{S} of the set of devices 130, the lasers in output ports other than O_{S}, for example ports O₀, O₁, . . ., O_{S-1} O_{S+1}, . . . , O_{K-1}, are retuned to send messages to targets at scheduled times. Suppose that K is an integer such that an output laser can be tuned in an amount of time not greater than (K−1)·(T_{P}+Δ) units of time. Then the data flow through the system is as follows. A packet flows through output port O₀ during the time interval TI₀=[t₀, t₀+T_{P}], through output port O₁ during the time interval TI₁=[t₀+T_{P}+Δ, t₀+2T_{P}+Δ], through the output port 02 during the time interval TI₂=[t₀+2T_{P}+2Δ, t₀+3T_{P}+2Δ], and so forth so that another packet passes through output port O₀ during the time interval TI_{K}=[t₀+KT_{P}+KΔ, t₀+(K+1)T_{P}+KΔ].

Permission to send a packet from a device D_{A} to a device D_{B} through the controlled network is obtained by a request-to-send data packet RTS through the uncontrolled network to D_{B}. In response to the request-to-send packet, device D_{B} reserves an input line for the incoming data during the proper data receiving interval or intervals in case a message comprising several packets is sent. In the tunable output laser embodiment, packets are sent in K different time slots and a designated device can simultaneously receive J data packets.

In a second optical embodiment illustrated by FIGS. 3A and 3B, an output port 230 of the device 130 is adapted to send data by modulating a single wavelength λ. In one embodiment, no two output ports use the same wavelength λ. The input ports of a device are able to tune to each of the wavelengths of the devices. In case a device D_{A} sends a data packet to a device D_{B} in a time interval TI, the device D_{B} receives an RTS packet before the start of interval TI with sufficient time for the device D_{B} to set one of the input devices to receive at the frequency used by device D_{A}.

Input ports 240 and output ports 230 of a device D_{M} 130 are illustrated in FIG. 3B. The device input ports I₀, I₁, . . . , I_{K-1} are used to receive packets in a sequential, round robin manner. Each input port I_{A} receives a packet only once in every K time intervals, enabling K−1 time intervals to retune for the next packet. Control devices for the two systems may include tunable output lasers and tunable reception filters which may operate using the same control techniques.

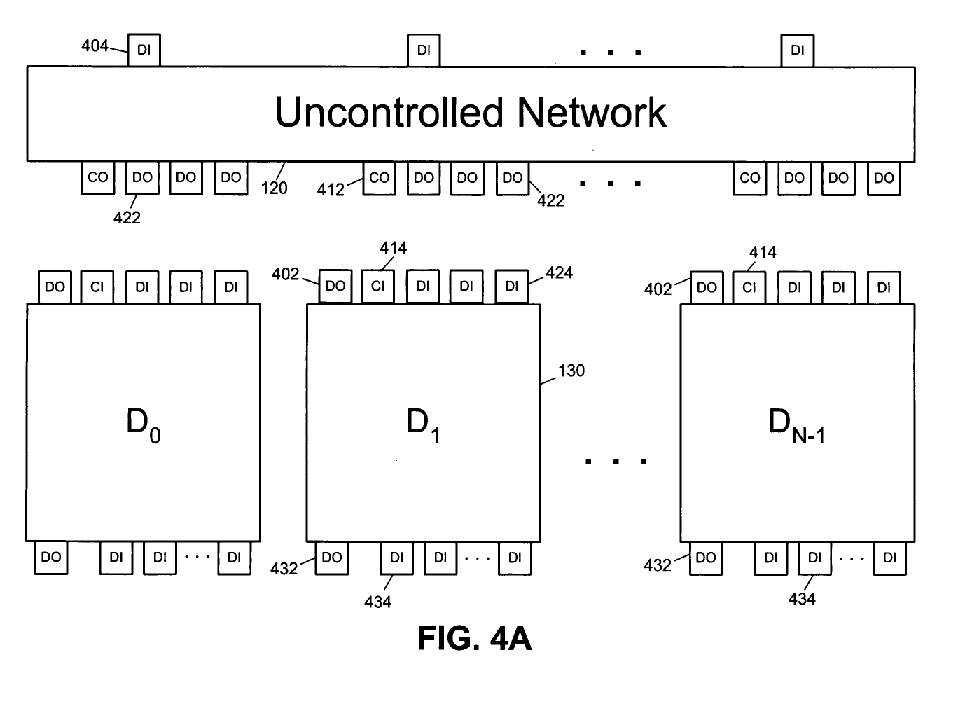

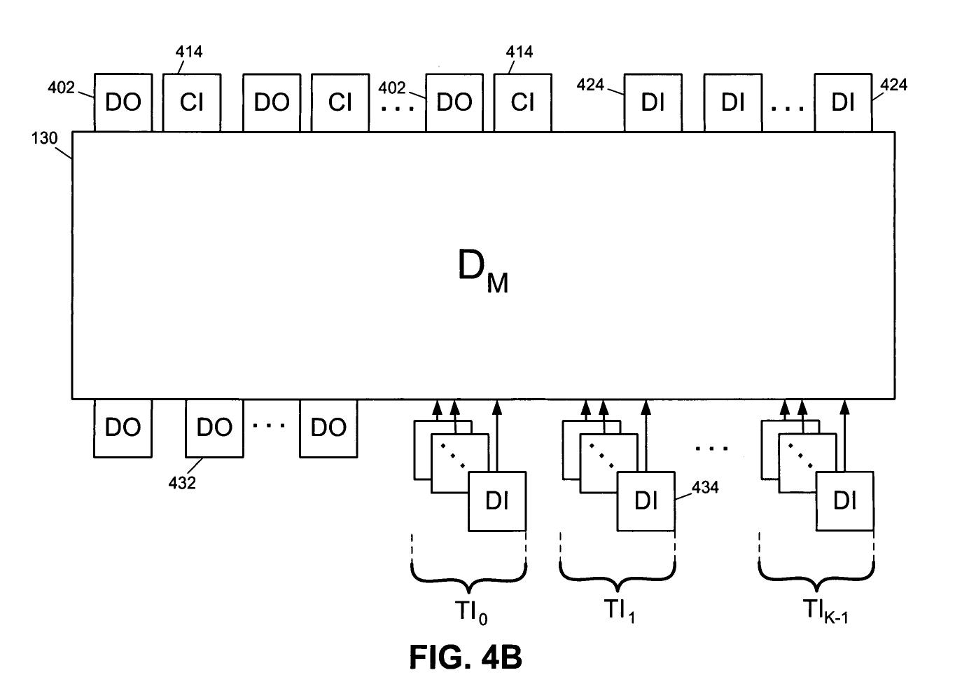

FIG. 4A illustrates N devices D₀, D₁, . . . , D_{N-1} that communicate via wireless channels. Two devices D_{A} and D_{B} 130 communicate via short messages through an uncontrolled network switch S 120 that, in many embodiments, may be a Data Vortex™ switch. The communication is accomplished by device D_{A} sending a short message to switch S and switch S relaying that message to device D_{B}. Long messages do not pass through switch S. Device D_{A} sends a long message directly to device D_{B} with scheduling of the long message handled by short messages through switch S. As in the systems corresponding to FIG. 3A, the system shown in FIG. 4A can operate using tunable transmitters or using tunable receivers. An embodiment with fixed frequency transmitters and tunable receivers is considered first. The tunable receiving devices 434 are illustrated in FIGS. 4A and 4B.

In an illustrative embodiment, N devices may include computing or data management devices. A device D_{A} sends a short data packet to device D_{B} via the uncontrolled network. In the present embodiment, the connection between the uncontrolled network and the devices may be a wireless connection. In some examples the uncontrolled network may be a Data Vortex™ network. Computing device data output ports DO 402 send data in the form of packets to the uncontrolled network data input device DI 404. In a simple embodiment, only one uncontrolled network S may be used and each computing device D may have a unique output port that sends data to switch S. In the simple embodiment, the uncontrolled switch S has N input devices with each input device tuned to receive data from a unique output transmitter of a sending device. In other embodiments, a computing device may have multiple output devices and correspondingly more input devices on an uncontrolled switch S. In still other embodiments, multiple uncontrolled networks may be implemented as described in incorporated references 1, 2, 3, 6, 7, 13, 15 and 17. A control signal input device CI 414 may be associated with each data output device 402. The Data Vortex™ switch has the ability to send a control signal from the control sending device CO 412 to a control signal input device CI 414. In case a control signal input device receives a blocking signal, the device informs an associated data sending device 402 not to transmit at a specific message packet transmission time.

In the uncontrolled portion of the network each switch input port 404 may be paired with a specific device output port 402 and the uncontrolled network operates as if the computing devices are hard-wired to the uncontrolled network. The Data Vortex™ switch has the ability to send multiple messages to the same receiving device, and therefore, the uncontrolled Data Vortex™ switch has multiple data output devices DO 422, each tuned to send data to a specific data input device DI 424 of a device D_{M} 130.

As in the other embodiments, data may be scheduled for sending through the controlled network. In a case whereby a receiving device D_{R} is scheduled to receive information from a sending device D_{S} when a certain criterion is met, prior to transmission of the packet the receiving device D_{R} tunes one of data input devices DI 434 to a pre-arranged frequency of the data output device DO 432 of the sending device D_{S}.

Referring to FIG. 4B, device D_{M} has K groups of data packet receiving devices DI 434, each of which receives data packets from the controlled network during mutually exclusive time intervals TI. During the time interval TI_{W}, a plurality of the devices DI 434 in the TI_{W} group can receive data simultaneously. During the time interval TI_{W}, devices in the group W are receiving data packets. Devices in the other groups are not receiving data. While input devices to device D_{M} are not receiving data, device D_{M} is tuning the input devices to receive data during a data receiving time interval. Data flow through the controlled network is managed by passing RTS packets through the uncontrolled switch.

In certain embodiments described herein, devices have a single output or input port which is capable of processing packets during each time interval. In alternate embodiments, multiple output or input ports of the type may be employed. In some embodiments described herein, devices have K inputs or outputs that process data, with only one device processing data at a given time. In alternate embodiments, the devices have K·J inputs with the device capable of processing data through J inputs at a designated time. Other modifications may be implemented to design a wide variety of systems using the techniques taught in the present description.

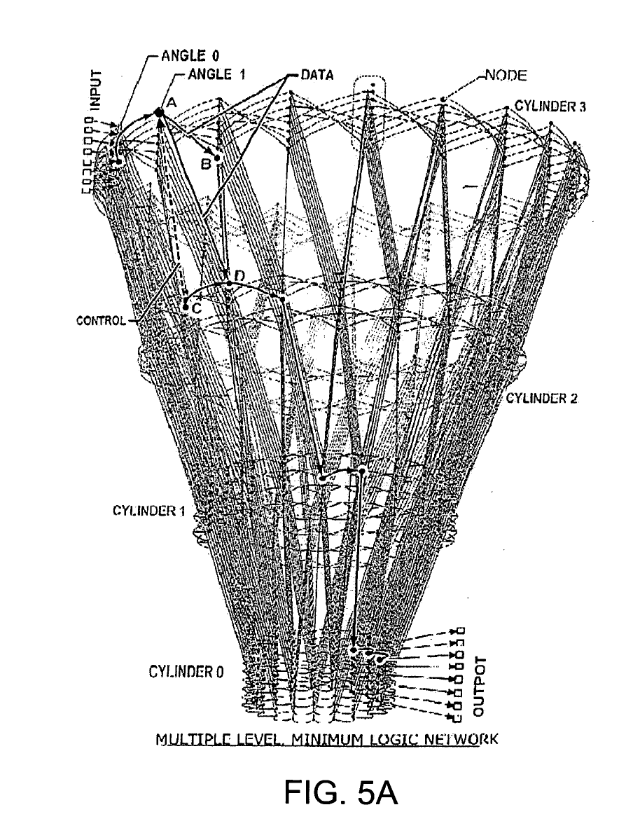

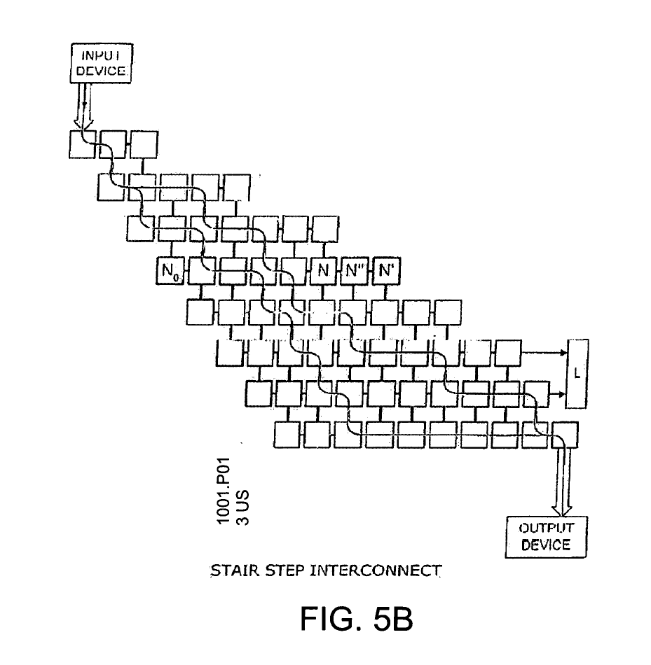

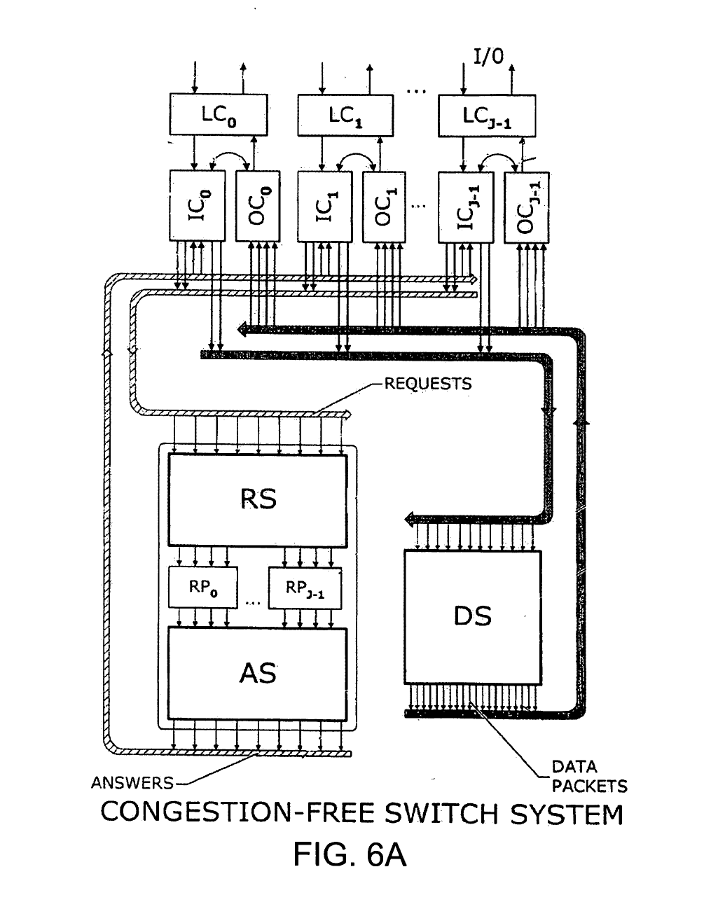

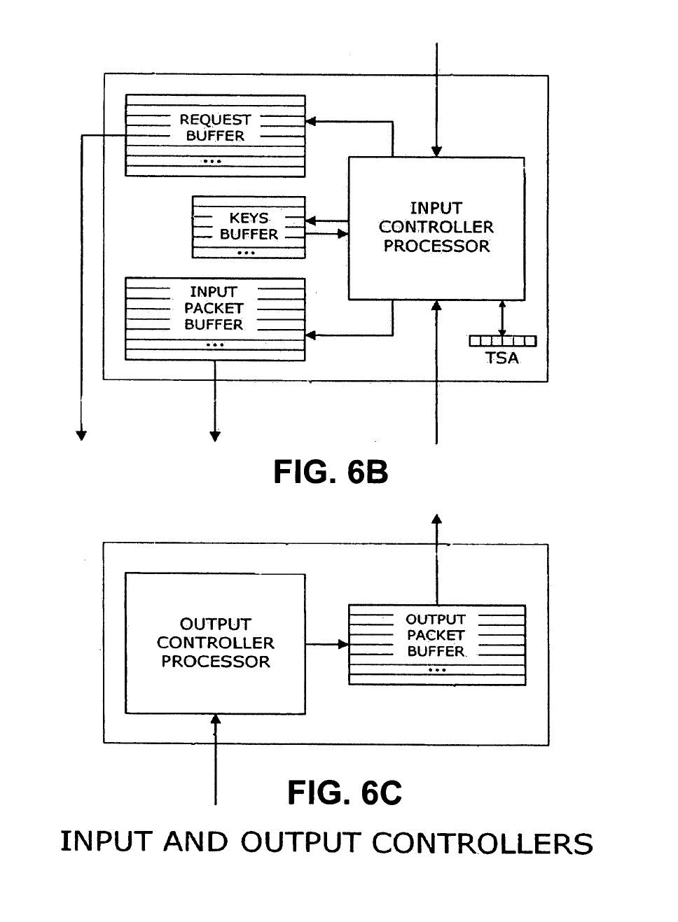

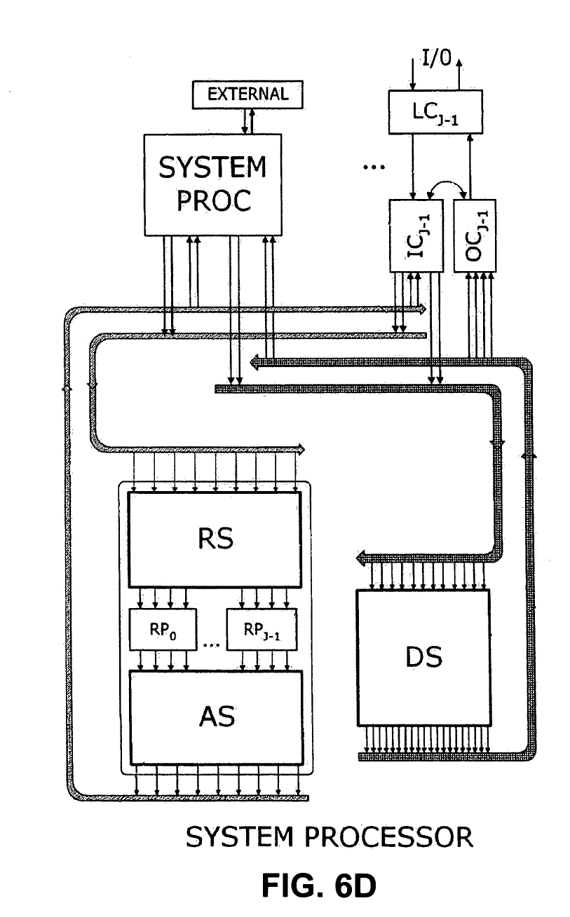

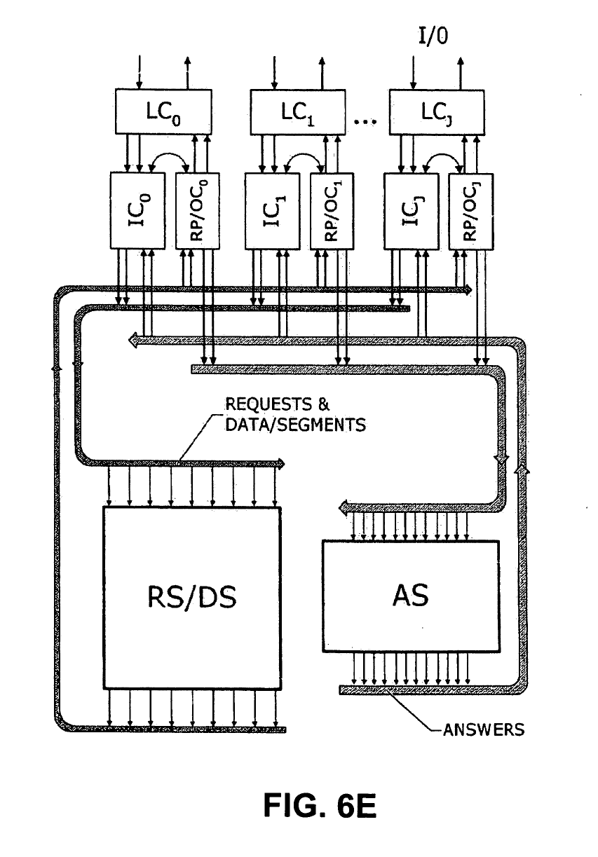

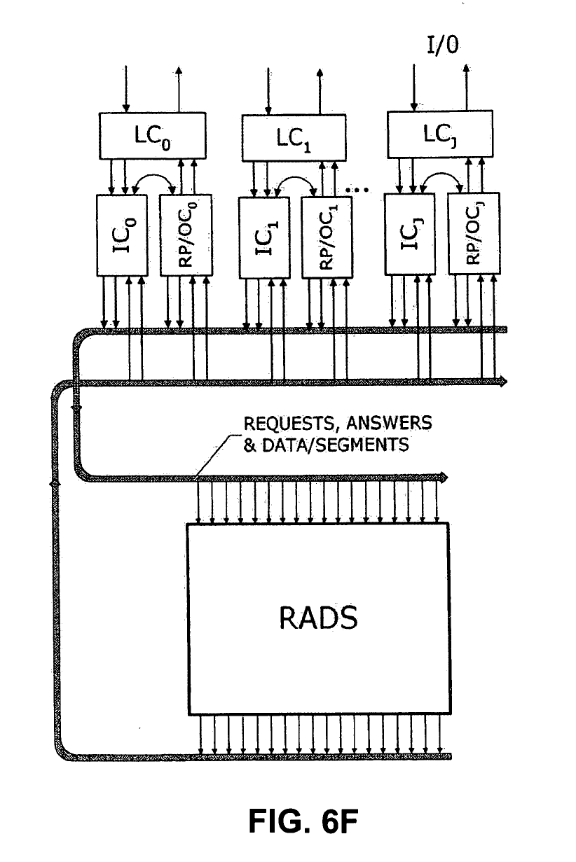

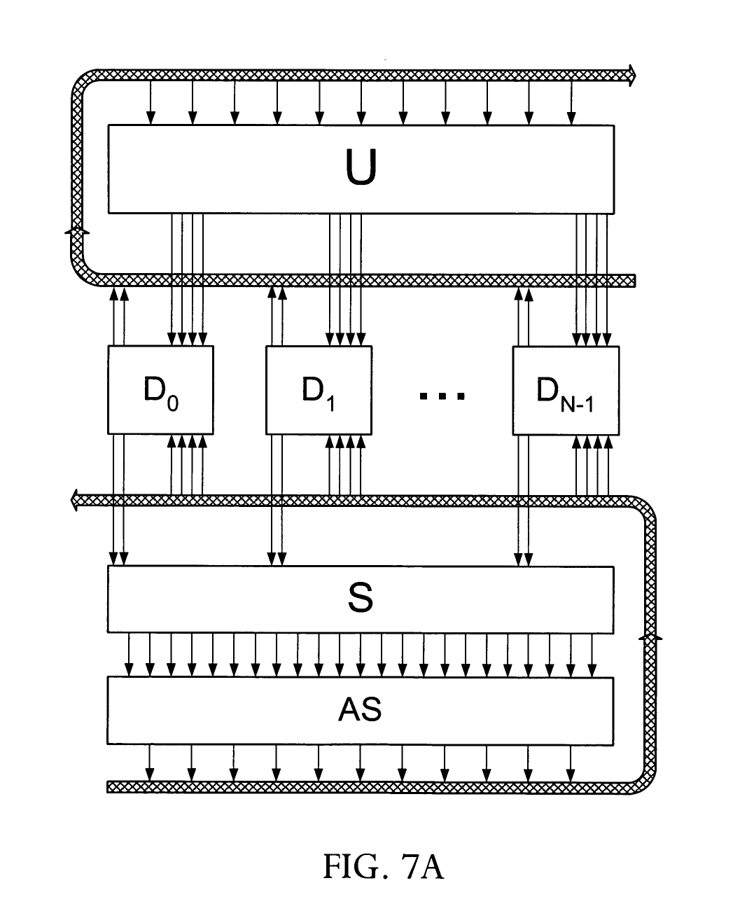

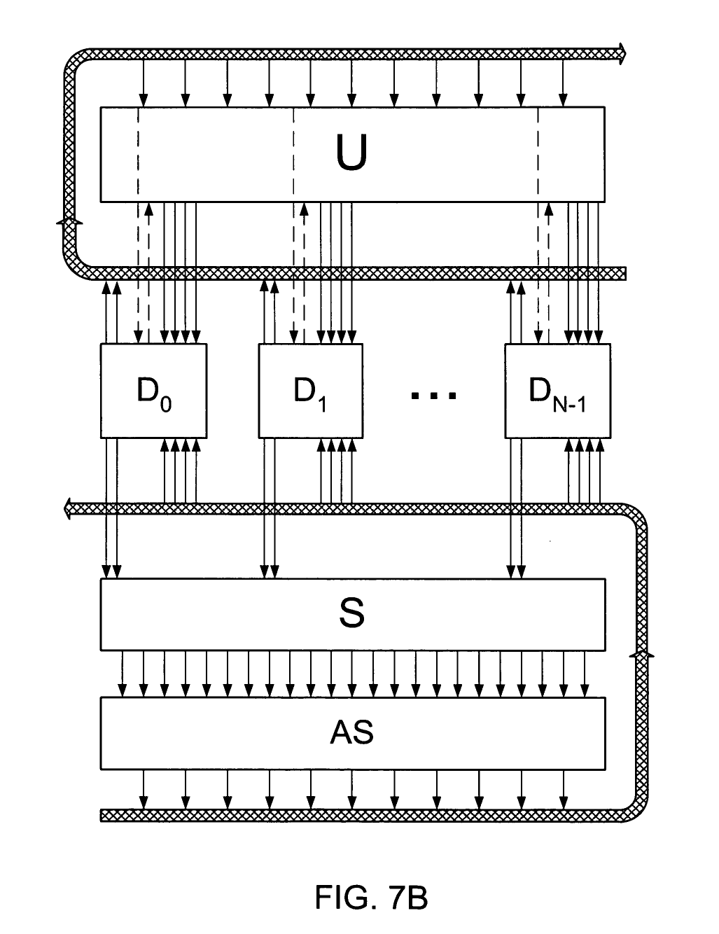

FIGS. 5A and 5B show an example of topology, logic, and use of a revolutionary interconnect structure that is termed a “Multiple Level Minimum Logic” (MLML) network and has also been referred to as the “Data Vortex”. Two types of multiple-level, minimum-logic (MLML) interconnect structures can be used in systems such as those disclosed in FIGS. 6A through 6F and FIGS. 7A and 7B. One type of interconnect structure disclosed in FIG. 5A can be called a “Data Vortex switch” and has a structure with multiple levels arranged in circular shift registers in the form of rings. In a second type of interconnect structure described in FIG. 5B and termed herein a “stair-step interconnect”, a portion of each ring of the Data Vortex switch structure is omitted so that each level includes a collection of non-circular shift registers.

In FIGS. 6A. through 6F, stair-step switches of the types described in FIG. 5B can be used to carry data. The stair-step switches are also used to carry data in the scheduled data switches described in FIGS. 7A and 7B. Multiple copies of the stair-step switches can be used to decrease latency of the last bit of each packet segment and also increase bandwidth of the interconnect structure. In embodiments using multiple switches, FIGS. 6A through 6F disclose a technique of decomposing packet segments into sub-segments and then simultaneously sending the sub-segments through a set or stack of stair-step switches, preventing any two sub-segments from passing through the same switch in the set. Each stair-step switch in the set is followed by an additional switch composed of a plurality of crossbar switches. The same structure, including a stack of stair-step switches followed by plurality of crossbar switches with one crossbar for each shift register of the exit level of the stair-step switch, can be used to carry the data in the scheduled data switches in FIGS. 7A and 7B.

The structures and operating methods disclosed herein have an error correction capability for correcting errors in payloads of data packet segments and for correcting errors resulting from misrouted data packet sub-segments. In some embodiments, the illustrative system performs error correction for data packet segments that are routed through stacks of networks, including network stacks with individual networks in the stack having the stair-step configuration depicted in FIGURE 5B. In other embodiments, the illustrative system performs error correction in network stacks with individual stack member networks having a Multiple-Level, Minimum-Logic (MLML) or Data Vortex configuration as disclosed in FIG. 5A.

Various embodiments of the disclosed system correct errors in data packet segments that are routed through stacks of networks with individual networks in the stack having the stair-step design illustrated in FIG. 5B and individual switches in the stack are followed by a plurality of crossbar switches. A crossbar switch is associated with individual bottom-level shift registers of the stair-step interconnect structures of the stack.

Some of the illustrative structures and operating methods correct errors occurring in systems that decompose data packet segments into sub-segments and a sub-segment fails to exit through an output port of a stair-step interconnect structure, for example the sub-segment is discarded by the switch. Various embodiments can correct errors for packets entering request and answer switches disclosed in FIGS. 6A through 6F, and also for packets entering uncontrolled switches described in computing and storage area networks taught in FIGS. 7A and 7B. Accordingly, the disclosed structures and associated operating techniques may be used in a wide class of systems that include data switching capability. Such systems may include switches that are neither MLML switches nor stair-step switches. The technology could, for example, be applied to stacks of crossbar switches or stacks of multiple hop networks, including toroidal networks, Clos networks, and fat-tree networks.

FIGS. 6A through 6F describe a system that includes a plurality of stair-step interconnect structures in a data switch with input of data controlled by request processors. FIGS. 7A and 7B disclose a system with a plurality of stair-step interconnect structures in scheduled networks. For such systems with K·N switches arranged in a stack of stair-step interconnect structures, with input devices capable of inserting K·N data streams into the switch stack. Many embodiments are possible for such a system. One example embodiment is a system that operates on full data packet segments, without decomposing the packets into sub-segments, and has an input device that can simultaneously insert K·N segments into a stack of stair-step interconnect structures. Each segment is inserted into a separate switch in the stack. In another example embodiment, data packet segments are decomposed into N sub-segments, each with the same header, and an input device is capable of simultaneously inserting two packet segments into the structure. Each of the resulting K·N sub-segments is inserted into a separate switch in the stack. In a third example embodiment, data packet segments are decomposed into K·N sub-segments, each with the same header, and an input device is capable of simultaneously inserting all K·N sub-segments of a particular packet segment. Each sub-segment inserts into a separate switch in the stack of stair-step switches. In systems that use H header bits to route a sub-segment through a stair-step interconnect structure, H header bits are included per packet segment in the first embodiment, N·H header bits per packet segment are included in the second embodiment, and K·N·H header bits per packet segment are used in the third embodiment. Accordingly, the first embodiment maximizes the ratio of payload to header.

FIGS. 6A through 6F disclose a system with input controllers and request processors. The input controller sends requests to a request processor to schedule data through the data switch. In FIGS. 7A and 7B, a request to schedule data to a target output port is sent to a request processor that controls data sent to that output port. Requests for scheduling data through switches in the references are analogous or similar. In a system embodiment that decomposes data packet segments into K·N sub-segments, for example the third embodiment hereinabove, the request specifies a set of available times the K·N packet sub-segments can be inserted into the switch. In a system embodiment that decomposes data packet segments into N sub-segments, for example the second embodiment hereinabove, the request specifies two sets of available times, one for each of the two sets of N stair-step switches. In a system embodiment that operates on full data packet segments, for example the first embodiment hereinabove, the request specifies K·N sets of available times, one set for each data packet segment. Therefore, the logic to schedule the data through the stack of stair-step switches is simplest for the third embodiment and most complicated for the first embodiment. The more complicated logic of the first embodiment also has request packets that contain more data, so that the amount of traffic though the request and answer switches disclosed in FIGS. 6A through 6F, and through the unscheduled switches disclosed in FIGS. 7A and 7B is greatest in the first embodiment and least in the third embodiment.

FIG. 5A is a schematic pictorial diagram illustrating a four-cylinder, eight-row network that exemplifies the multiple-level, minimum-logic (MLML) networks taught in U.S. Pat. No. 5,996,020. Data in the form of a serial message enters the network at INPUT terminals to the network which are located at an outermost cylinder, shown as cylinder 3 at the top of FIG. 5A, and moves from node to node towards a target output port that is specified in a header of the message. Data always moves to a node at the next angle in one time period. A message moves toward an inner cylinder shown at a lower level in FIG. 5A whenever such a move takes the message closer to the target port.

The network has two kinds of transmission paths: one for data, and another for control information. In an illustrative embodiment, all nodes in the network may have the same design. In other embodiments, the nodes may have mutually different designs and characteristics. A node accepts data from a node on the same cylinder or from a cylinder outward from the node's cylinder, and sends data to node on the same cylinder or to a cylinder inward from the node's cylinder. Messages move in uniform rotation around the central axis in the sense that the first bit of a message at a given level uniformly moves around the cylinder. When a message bit moves from a cylinder to a more inward cylinder, the message bits synchronize exactly with messages at the inward cylinder. Data can enter the interconnect or network at one or more columns or angles, and can exit at one or more columns or angles, depending upon the application or embodiment.

A node sends control information to a more outward positioned cylinder and receives control information from a more inward positioned cylinder. Control information is transmitted to a node at the same angle or column. Control information is also transmitted from a node on the outermost cylinder to an input port to notify the input port when a node on the outermost cylinder that is capable of receiving a message from the input port is unable to accept the message. Similarly, an output port can send control information to a node on the innermost cylinder whenever the output port cannot accept data. In general, a node on any cylinder sends a control signal to inform a node or input port that the control signal sending node cannot receive a message. A node receives a control signal from a node on a more inward positioned cylinder or an output port. The control signal informs the recipient of the control signal whether the recipient may send a message to a third node on a cylinder more inward from the cylinder of the recipient node.

In the network shown in FIGURE 5A, if a node A sends a message to a node B on the same cylinder, and node B receives data from a node J on an outer cylinder, then the node A independently sends control information to the node J. Node B, which receives messages from nodes A and J, does not participate in the exchange of control information between nodes A and J. Control-signal and data-routing topologies and message-routing schemes are discussed in detail hereinafter.

In U.S. Pat. No. 5,996,020 the terms “cylinder” and “angle” are used in reference to position. These terms are analogous to “level” and “column,” respectively, used in U.S. Pat. No. 6,289,021, and in the present description. Data moves horizontally or diagonally from one cylinder to the next, and control information is sent outward to a node at the same angle.

FIG. 5B is a schematic diagram showing a stair-step interconnect structure. The stair-step interconnect structure has only one input column, no connections back from right to left, and no FIFOs. The structure may, however, have multiple output columns. A property of some embodiments of such interconnects is existence of an integer OUTLIM such that when no output row is sent more than OUTLIM messages during the same cycle, then each message establishes a wormhole connection path from an input port to an output port.

In another embodiment of the stair-step interconnect, multicasting of messages is supported by the use of multiple headers for a single payload. Multicasting occurs when a payload from a single input port is sent to multiple output ports during one time cycle. Each header specifies the target address for the payload, and the address can be any output port. The rule that no output port can receive a message from more than one input port during the same cycle is still observed. The first header is processed as described hereinbefore and the control logic sets an internal latch which directs the flow of the subsequent payload. Immediately following the first header, a second header follows the path of the first header until reaching a cell where the address bits determinative of the route for that level are different. Here the second header is routed in a different direction than the first. An additional latch in the cell represents and controls a bifurcated flow out of the cell. Stated differently, the second header follows the first header until the address indicates a different direction and the cell makes connections such that subsequent traffic exits the cell in both directions. Similarly, a third header follows the path established by the first two until the header bit determinative for the level indicates branching in a different direction. When a header moves left to right through a cell, the header always sends a busy signal upward indicating an inability to receive a message from above.

The rule is always followed for the first, second, and any other headers. Stated differently, when a cell sends a busy signal to upward then the control signal is maintained until all headers are processed, preventing a second header from attempting to use the path established by a first header. The number of headers permitted is a function of timing signals, which can be external to the chip. The multicasting embodiment of the stair-step interconnect can accommodate messages with one, two, three or more headers at different times under control of an external timing signal. Messages that are not multicast have only a single header followed by an empty header, for example all zeros, in the place of the second and third headers. Once all the headers in a cycle are processed the payload immediately follows the last header, as discussed hereinabove. In other embodiments, multicasting is accomplished by including a special multicast flag in the header of the message and sending the message to a target output that in turn sends copies of the message to a set of destinations associated with said target output.

While the present disclosure describes various embodiments, these embodiments are to be understood as illustrative and do not limit the claim scope. Many variations, modifications, additions and improvements of the described embodiments are possible. For example, those having ordinary skill in the art will readily implement the steps necessary to provide the structures and methods disclosed herein, and will understand that the process parameters, materials, and dimensions are given by way of example only. The parameters, materials, components, and dimensions can be varied to achieve the desired structure as well as modifications, which are within the scope of the claims. Variations and modifications of the embodiments disclosed herein may also be made while remaining within the scope of the following claims.

What is claimed is:

1. An interconnect structure comprising:
a plurality of network-connected devices; and
a logic coupled to the plurality of network-connected devices and adapted to control a first subset of the network-connected devices to transmit data and simultaneously control a second subset of the network-connected devices to prepare for data transmission at a future time, the logic adapted to execute an operation that activates a data transmission action upon realization of at least one predetermined criterion.

2. The interconnect structure according to claim 1 further comprising:
the logic adapted to execute a request-to-send-data-packet operation, a packet comprising a plurality of fields including at least a field that describes data to be sent, a field that designates a target device for the data, and a field that describes at least one criterion to be realized for the data to be transmitted.

3. The interconnect structure according to claim 2 further comprising:
the packet that further comprises a field that identifies a target input port of the target device, and a field that assigns priority to transmission.

4. The interconnect structure according to claim 1 wherein:
the logic is adapted to schedule a designated receiving device to receive data at a designated time and a designated input port, the time and input port designated in fields of a request-to-send-data-packet instruction.

5. The interconnect structure according to claim 1 further comprising:
a plurality of computational devices; and
the logic adapted to control the plurality of computational devices to perform a same function on different data sets and report completion of the function to a master device, the master device controlled to send request-to-send-data-packets to computational devices that send data and that receive data, the sending computational devices receiving a request-to-send-data-packet from the master device that directs to send data when a designated criterion is realized, and the receiving computational devices receiving a request-to-send-data-packet from the master device that prepares for receipt during a designated receiving time interval.

6. The interconnect structure according to claim 1 further comprising:
the logic adapted to control the plurality of computational devices as at least one receiving device and at least one sending device, a first receiving device controlled to send an request-to-send-data-packet to a first sending device that requests designated data to be sent to the first receiving device as soon as criteria designated in the request-to-send-data-packet are realized.

7. The interconnect structure according to claim 1 further comprising:
the logic adapted to control the plurality of network-connected devices via a master device that controls data flow among at least a subset of the network-connected devices including control of time and location for sending individual data packets whereby message time of flight is known in advance and multiple messages can be transmitted to a designated device with arrival time of the multiple messages predetermined by deterministic latency.

8. The interconnect structure according to claim 1 further comprising:
an uncontrolled electronic switch adapted to multicast data among a set of network-connected devices divided into a collection of multicast group subsets whereby an individual device is in no more than one subset and all subsets contain at least two devices, the network-connected devices adapted to communicate via request-to-send-data-packets that include a multicast field designating multicast transmission.

9. The interconnect structure according to claim 8 further comprising:
a sending device adapted to multicast to a multicast group that sends a designated time and place multicast message through the uncontrolled electronic switch indicating to receiving devices in the multicast group a designated time at which the receiving devices are scheduled to receive a message, the receiving devices being responsive to the message by opening a designated multicast port at the designated time.
